(19) United States
(12) Patent Application Publication
(10) Pub. No.: US 2017/0033765 A1
(43) Pub. Date: Feb. 2, 2017

(54) ACOUSTIC WAVE DEVICE AND MODULE

(71) Applicant: TAIYO YUDEN CO., LTD., Tokyo (JP)

(72) Inventors: Akira MORIYA, Tokyo (JP); Osamu KAWACHI, Tokyo (JP)

(73) Assignee: TAIYO YUDEN CO., LTD., Tokyo (JP)

(21) Appl. No.: 15/217,105

(22) Filed: Jul. 22, 2016

(30) Foreign Application Priority Data
Jul. 29, 2015 (JP) 2015-150158

(51) Int. Cl. H03H 9/02; H03H 9/145; H03H 9/64

(52) U.S. Cl. CPC H03H 9/02834; H03H 9/02574; H03H 9/64; H03H 9/145

(57) ABSTRACT

An acoustic wave device includes: a support substrate; a piezoelectric substrate bonded on an upper surface of the support substrate at room temperature and made of a different material from the support substrate; a comb-shaped electrode formed on an upper surface of the piezoelectric substrate and exciting an acoustic wave; and an amorphous layer formed between the support substrate and the piezoelectric substrate.

### CROSS-REFERENCE TO RELATED APPLICATION

This application is based upon and claims the benefit of priority of the prior Japanese Patent Application No. 2015-150158, filed on Jul. 29, 2015, the entire contents of which are incorporated herein by reference.

### FIELD

A certain aspect of the present invention relates to an acoustic wave device and a module.

### BACKGROUND

It has been known that a piezoelectric substrate is bonded on a support substrate to improve the frequency-temperature characteristic of an acoustic wave device using a surface acoustic wave of the piezoelectric substrate. Japanese Patent Application Publication No. 2004-186868 (Patent Document 1) discloses an art that uses a lithium tantalate substrate as the piezoelectric substrate and a sapphire substrate as the support substrate, and makes the thickness of the support substrate more than three times greater than the thickness of the piezoelectric substrate, and the thickness of the piezoelectric substrate more than ten times greater than the wavelength of the surface acoustic wave when the piezoelectric substrate is bonded on the support substrate at room temperature. Japanese Patent Application Publication No. 2012-105191 (Patent Document 2) discloses an art that uses a lithium tantalate substrate for the support substrate as for the piezoelectric substrate. Japanese Patent Application Publication No. 2015-92782 (Patent Document 3) discloses that a medium layer is located between the support substrate and the piezoelectric substrate.

When a piezoelectric substrate is bonded on a support substrate at room temperature, spurious due to a bulk wave reflected by the boundary surface between the support substrate and the piezoelectric substrate becomes a problem. The reflection of the bulk wave by the boundary surface does not occur when the support substrate and the piezoelectric substrate are made of the same material as disclosed in Patent Document 2, or when a medium layer is inserted between the support substrate and the piezoelectric substrate as disclosed in Patent Document 3. As disclosed in Patent Document 1, to reduce the spurious, the thickness of the piezoelectric substrate is made more than ten times greater than the wavelength of the surface acoustic wave. However, when the substrate is thinned to reduce its size, the thickness of the support substrate relative to the substrate thickness decreases. This reduces the degree of improvement of the frequency-temperature characteristic. Additionally, the substrate is broken by a heat cycle more easily.

### SUMMARY OF THE INVENTION

According to an aspect of the present invention, there is provided an acoustic wave device including: a support substrate; a piezoelectric substrate bonded on an upper surface of the support substrate at room temperature and made of a different material from the support substrate; a comb-shaped electrode formed on an upper surface of the piezoelectric substrate and exciting an acoustic wave; and an amorphous layer formed between the support substrate and the piezoelectric substrate.

According to another aspect of the present invention, there is provided a module including: the above acoustic wave device.

### BRIEF DESCRIPTION OF THE DRAWINGS

FIG. 1 is a perspective view of an acoustic wave device in accordance with a first embodiment and a comparative example;

FIG. 2A and FIG. 2B are graphs of a film thickness T1 of a support substrate and a film thickness T2 of a piezoelectric substrate with respect to frequency when a film thickness T1+T2 is 150 μm and 100 μm, respectively;

FIG. 3A through FIG. 3D are graphs of admittance versus frequency;

FIG. 4A and FIG. 4B are graphs of attenuation versus frequency;

FIG. 5A through FIG. 5C are graphs of the film thickness T1 of the support substrate and the film thickness T2 of the piezoelectric substrate with respect to frequency when the film thickness T1+T2 is 150 μm, 100 μm, and 50 μm, respectively;

FIG. 6A is a circuit diagram of a ladder-type filter in accordance with a second embodiment, and FIG. 6B is a block diagram of a multiplexer in accordance with a variation of the second embodiment; and

FIG. 7 is a block diagram of a system including a module in accordance with a third embodiment.

### DETAILED DESCRIPTION

Embodiments of the present invention will be described with reference to the accompanying drawings.

### First Embodiment

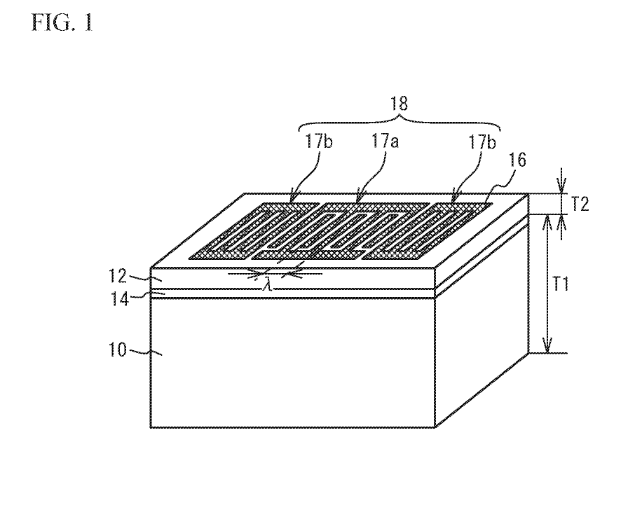

FIG. 1 is a perspective view of an acoustic wave device in accordance with a first embodiment and a comparative example. As illustrated in FIG. 1, a piezoelectric substrate 12 with a film thickness T2 is located on the upper surface of a support substrate 10 with a film thickness T1, and the lower surface of the piezoelectric substrate 12 is bonded on the upper surface of the support substrate 10. The support substrate 10 is a sapphire substrate. The piezoelectric substrate 12 is a lithium tantalate substrate. An amorphous layer 14 is formed between the upper surface of the support substrate 10 and the lower surface of the piezoelectric substrate 12. The thickness of the amorphous layer 14 is very thin such as 10 nm or less, and thus almost negligible relative to the film thicknesses T1 and T2.

A one port resonator 18 is formed on the upper surface of the piezoelectric substrate 12. The one port resonator 18 includes an Interdigital Transducer (IDT) 17a and reflection electrodes 17b that are formed of a metal layer 16 made of aluminum (Al) and formed on the piezoelectric substrate 12. The IDT 17a includes two comb-shaped electrodes. The reflection electrodes 17b are located at both sides of the IDT 17a. The comb-shaped electrode of the IDT 17a excites a surface acoustic wave (mainly, an SH wave). The excited acoustic wave is reflected by the reflection electrodes 17b. The acoustic wave propagates in the X-axis direction in the crystal orientation of the piezoelectric substrate 12. The wavelength λ of the surface acoustic wave excited by the IDT 17a corresponds to twice the pitch of the electrode fingers of the IDT 17a. The surface acoustic wave is an acoustic wave contributing to the function of the acoustic wave device in accordance with the first embodiment. The acoustic wave excited by the IDT 17a may be a boundary acoustic wave or a Love wave.

The support substrate 10 and the piezoelectric substrate 12 are bonded together at room temperature. The description will be given of an example of a method of bonding the support substrate 10 and the piezoelectric substrate 12 at room temperature. First, the upper surface of the support substrate 10 and the lower surface of the piezoelectric substrate 12 are irradiated with the ion beam of an inert gas, the neutral beam, or the plasma. This process forms an amorphous layer of several nanometers or less on the upper surface of the support substrate 10 and the lower surface of the piezoelectric substrate 12. Dangling bonds are formed on the surface of the amorphous layer. The dangling bonds make the upper surface of the support substrate 10 and the lower surface of the piezoelectric substrate 12 active. The dangling bonds on the upper surface of the support substrate 10 are bonded to the dangling bonds on the lower surface of the piezoelectric substrate 12. Accordingly, the support substrate 10 and the piezoelectric substrate 12 are bonded together at room temperature. The amorphous layer 14 is integrally interposed between the bonded support substrate 10 and the bonded piezoelectric substrate 12. The amorphous layer 14 has a thickness of, for example, 1 to 8 nm. Here, the room temperature is 100° C. or less and −20° C. or greater, more preferably 80° C. or less and 0° C. or greater.

Since the support substrate 10 and the piezoelectric substrate 12 are bonded together at room temperature, the stress applied to the support substrate 10 and the piezoelectric substrate 12 is reduced. For example, when the acoustic wave device is used, a temperature higher or lower than the room temperature is applied to the acoustic wave device. The room-temperature bonded acoustic wave device can reduce a thermal stress at both the high and low temperatures. The room-temperature bonded acoustic wave device inhibits the substrate from being broken in a temperature cycling test that repeats a high temperature (e.g., 150° C.) and a low temperature (e.g., −65° C.). Whether the acoustic wave device was bonded at room temperature is checked by the temperature dependence of the residual stress. That is, the residual stress becomes smallest at the temperature at which the bonding was performed.

The X-axis of the crystal orientation of the lithium tantalate has a linear thermal expansion coefficient of 16.1 ppm/° C. Thus, a rotated Y-cut X-propagation lithium tantalate substrate has a large linear thermal expansion coefficient in the propagation direction of the acoustic wave. When the acoustic wave device is formed with a lithium tantalate substrate, the lithium tantalate substrate expands and contracts depending on temperature. Thus, the temperature dependence of the frequency, such as the resonant frequency, of the acoustic wave device increases. In the structure illustrated in FIG. 1, the sapphire substrate has a linear thermal expansion coefficient of 7.7 ppm/° C., which is small. Accordingly, the support substrate 10 inhibits the piezoelectric substrate from expanding and contracting. Therefore, the temperature dependence of the frequency of the acoustic wave device is reduced.

When the support substrate 10 is a sapphire substrate and the piezoelectric substrate 12 is a lithium tantalate substrate, the thickness of the support substrate 10 is made more than three times greater than the thickness of the piezoelectric substrate 12 to improve the frequency-temperature characteristic of the acoustic wave device as disclosed in Patent Document 1.

When the piezoelectric substrate 12 is bonded on the support substrate 10 at room temperature, the boundary surface between the piezoelectric substrate 12 and the support substrate 10 becomes flat. Thus, the bulk wave excited when the IDT 17a excites a surface acoustic wave is reflected by the amorphous layer 14 of the boundary surface between the piezoelectric substrate 12 and the support substrate 10. When the reflected bulk wave reaches the IDT 17a, it forms spurious.

As disclosed in Patent Document 1, to reduce the spurious due to the reflection of the bulk wave, the thickness of the piezoelectric substrate 12 is made more than ten times greater than the wavelength of the surface acoustic wave excited by the IDT 17a.

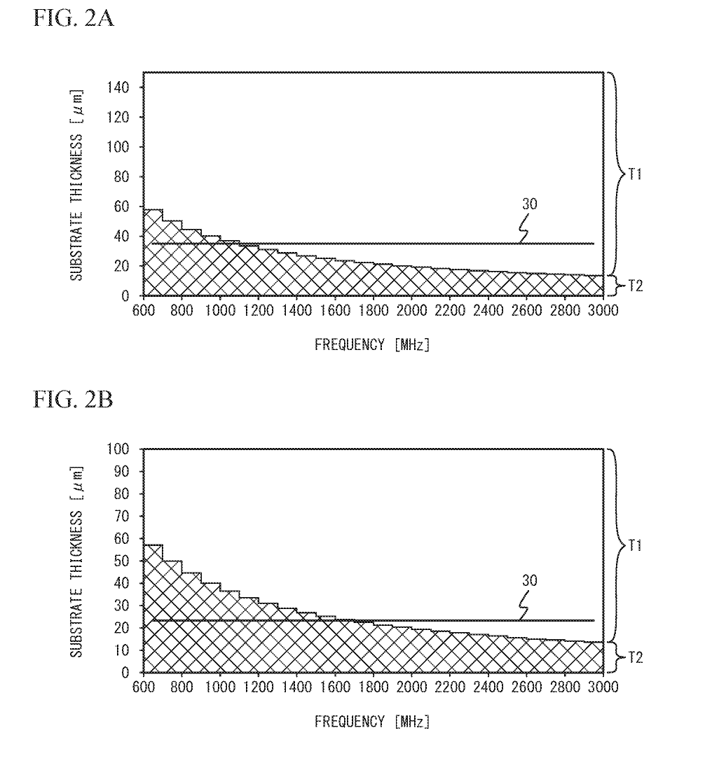

To reduce the acoustic wave device in size, the reduction of the total film thickness T1+T2 of the support substrate 10 and the piezoelectric substrate 12 will be considered. FIG. 2A and FIG. 2B are graphs of the film thickness T1 of the support substrate 10 and the film thickness T2 of the piezoelectric substrate 12 with respect to frequency when the film thickness T1+T2 is 150 μm and 100 μm, respectively. To reduce the spurious due to the bulk wave, the film thickness T2 of the piezoelectric substrate 12 is configured to be ten times greater than the wavelength λ of the acoustic wave. The support substrate 10 is a sapphire substrate, the piezoelectric substrate 12 is a 42° rotated Y-cut X-propagation lithium tantalate substrate, and the acoustic velocity of the SH wave is 4000 m/s.

As illustrated in FIG. 2A and FIG. 2B, as the frequency decreases, the ratio of T1 to T1+T2 decreases. Thus, the function of the support substrate 10 that inhibits the expansion and contraction of the piezoelectric substrate 12 is disturbed. For example, as illustrated in Patent Document 1, a solid line 30 at which T2/T1=1/3 is illustrated. According to Patent Document 1, when the film thickness T2 of the piezoelectric substrate 12 is greater than the thickness indicated by the solid line 30, the function of the support substrate 10 is disturbed. When the substrate thickness T1+T2 is 150 μm and the acoustic wave has a frequency of 1000 MHz or less, the support substrate 10 is non-functional. When the substrate thickness T1+T2 is 100 μm and the acoustic wave has a frequency of 1500 MHz or less, the support substrate 10 is non-functional. As described above, the reduction of the substrate thickness T1+T2 makes it difficult to maintain the function of the support substrate 10.

As described above, it is difficult to reduce the substrate thickness within a range between T1 and T2 disclosed in Patent Document 1. This is because the spurious due to the bulk wave reflected by the boundary surface increases when the film thickness T2 of the piezoelectric substrate 12 is made 10λ or less.

The spurious due to the bulk wave reflected by the boundary surface does not occur when both the support substrate 10 and the piezoelectric substrate 12 are lithium tantalate substrates as disclosed in Patent Document 2, or when a medium layer is inserted between the support substrate 10 and the piezoelectric substrate 12 that are not bonded together at room temperature as disclosed in Patent Document 3. Patent Document 3 discloses spurious due to the high-order acoustic wave of the SH wave. However, the spurious due to the high-order acoustic wave of the SH wave appears at frequency 1.2 to 1.5 times greater than the main response (the resonant frequency and the antiresonant frequency due to the SH wave), and differs from the spurious occurring in or in the immediate vicinity of the main response due to the bulk wave reflected by the boundary surface.

The investigation of the inventors reveals that the spurious due to the bulk wave is reduced when the film thickness T2 of the piezoelectric substrate 12 is made λ or less. This defies the common wisdom disclosed in Patent Document 1. Hereinafter, a description will be given of the investigation results at frequencies between 600 and 3000 MHz at which the acoustic wave device of a comb-shaped electrode is practically used.

Admittance with respect to frequency was simulated under the following condition.
Support substrate 10: a sapphire substrate, the thickness T1 is infinite.
Piezoelectric substrate 12: a 42° rotated Y-cut X-propagation lithium tantalate substrate, the film thickness T2 is 10λ, 1λ, 0.8λ, and 0.5λ.
IDT 17a: the wavelength λ is 4 μm, the duty ratio of the electrode finger (line/(line+space)) is 50%, the number of pairs is 120 pairs, and the aperture length is 30λ.

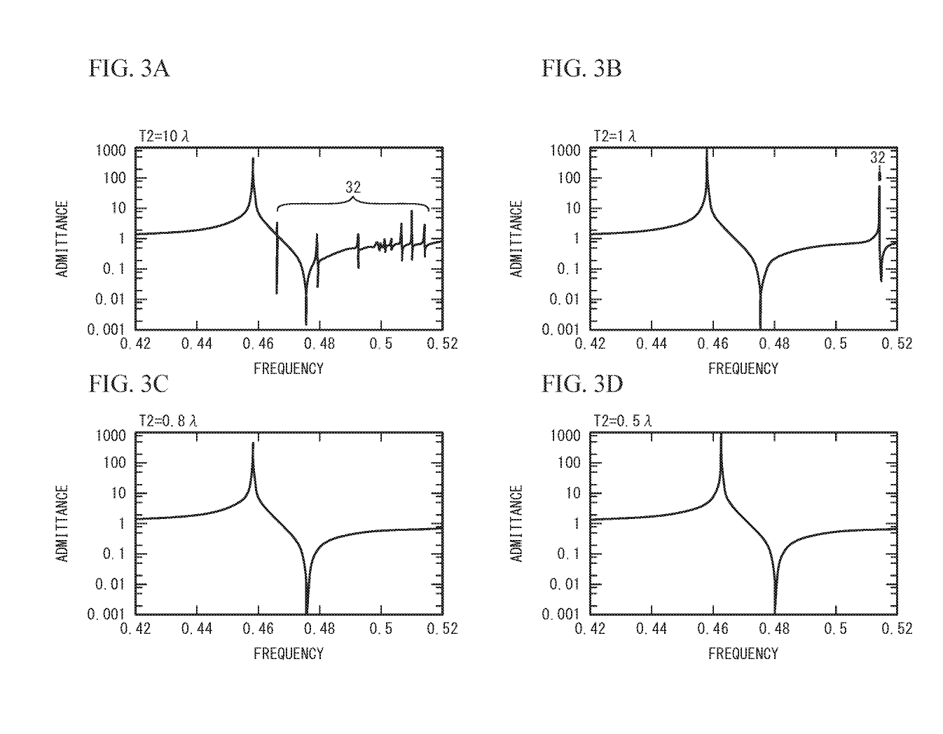

FIG. 3A through FIG. 3D are graphs of admittance versus frequency. The frequency is a normalized frequency. As illustrated in FIG. 3A, when the piezoelectric substrate 12 has a film thickness T2 of 10λ, spurious 32 due to the bulk wave is observed at frequencies higher than the resonant frequency. As illustrated in FIG. 3B, when T2 is 1λ, the spurious 32 due to the bulk wave is hardly observed. As illustrated in FIG. 3C and FIG. 3D, when T2 is 0.8λ and 0.5λ, the spurious due to the bulk wave is not observed. As described above, when the film thickness T2 of the piezoelectric substrate 12 is made λ or less, the spurious due to the reflection of the bulk wave by the boundary surface is reduced. Furthermore, when T2 is 0.8λ or less, the spurious is further reduced.

Attenuation with respect to frequency was then simulated under the following condition.
Support substrate 10: a sapphire substrate, the thickness T1 is approximately 152 μm.
Piezoelectric substrate 12: a 42° rotated Y-cut X-propagation lithium tantalate substrate, the film thickness T2 is 0.65λ in the first embodiment, and is 8.7λ in the first comparative example.
IDT 17a: the wavelength λ is 4.6 μm, the duty ratio of the electrode finger (line/(line+space)) is 50%, the number of pairs is 120 pairs, and the aperture length is 30λ.

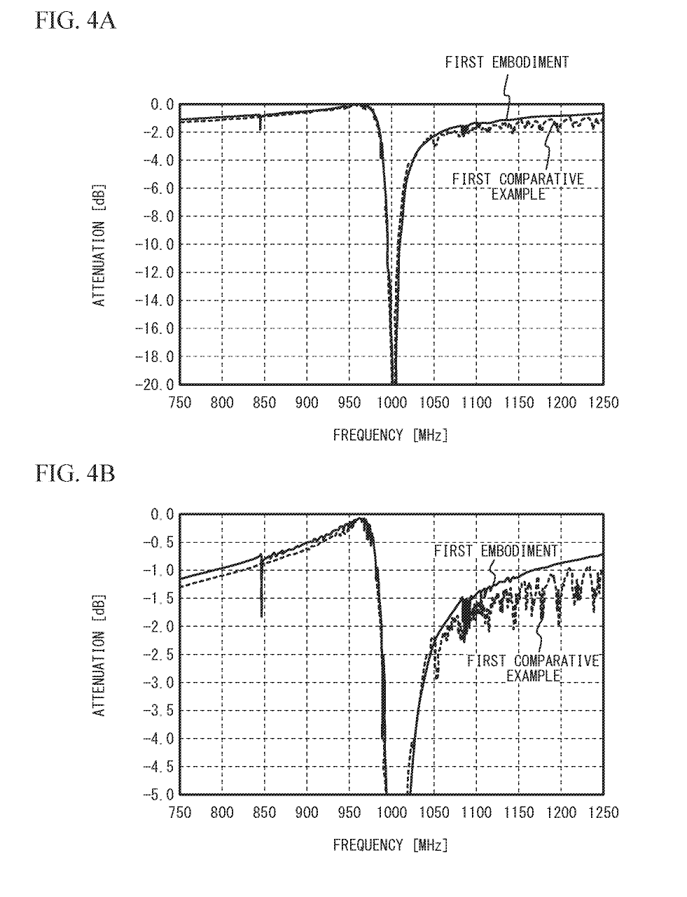

FIG. 4A and FIG. 4B are graphs of attenuation versus frequency. FIG. 4B is an enlarged view of FIG. 4A. As illustrated in FIG. 4A and FIG. 4B, in the first comparative example, spurious occurs in a frequency region higher than the antiresonant frequency. In the first embodiment, no spurious occurs.

As described above, it is revealed that the spurious due to the bulk wave is reduced when the film thickness T2 of the piezoelectric substrate 12 is made λ or less. The reason is not clear, but is considered to be because the propagation of the bulk wave in the film thickness direction is reduced when T2 is λ or less.

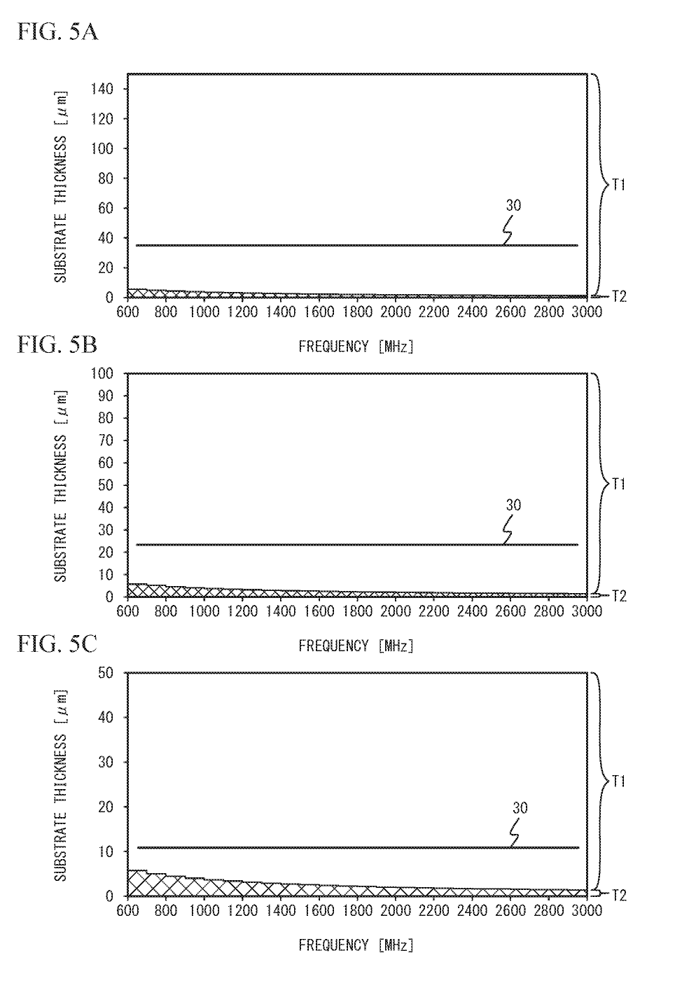

FIG. 5A through FIG. 5C are graphs of the film thickness T1 of the support substrate 10 and the film thickness T2 of the piezoelectric substrate 12 with respect to frequency when the film thickness T1+T2 is 150 μm, 100 μm, and 50 μm, respectively. The film thickness T2 of the piezoelectric substrate 12 is the wavelength λ of the acoustic wave. Other conditions are the same as those of FIG. 2A and FIG. 2B.

As illustrated in FIG. 5A through FIG. 5C, as the frequency increases, the ratio of T1 to T1+T2 decreases. However, at any frequencies, T2 is below the solid line 30. That is, the support substrate 10 can fulfill the function that inhibits the expansion and contraction of the piezoelectric substrate 12 at any frequencies. As illustrated in FIG. 5C, even when T1+T2 is 50 μm, the spurious is reduced, and the support substrate 10 maintains its function.

A temperature cycling test was conducted on a sample of which T1+T2 is approximately 150 μm. The temperature cycling test was conducted by repeating a cycle of room temperature, −65° C., room temperature, +150° C., and room temperature 1000 times. The film thicknesses of the first embodiment and the first comparative example are as follows.
First embodiment: T1=152 μm, T2=3 μm
First comparative example: T1=115 μm, T2=40 μm
Chip size: 1.04 mm×0.88 mm (a transmit filter), 1.04 mm×0.50 mm (a receive filter)

As the results of the temperature cycling test, a crack was formed in the first comparative example but was not formed in the first embodiment. This is because the crack is more easily formed in the support substrate 10 as the support substrate 10 becomes thinner and the thermal stress from the piezoelectric substrate 12 increases as the piezoelectric substrate 12 becomes thicker.

The problem of the reflection of the bulk wave by the boundary surface between the support substrate 10 and the piezoelectric substrate 12 is a unique problem that occurs when the support substrate 10 and the piezoelectric substrate 12 are made of different materials (have different acoustic impedances) and bonded together at room temperature. When it is assumed that the reason why the spurious due to the bulk wave is reduced when the film thickness T2 of the piezoelectric substrate 12 is λ or less is because the propagation of the bulk wave in the film thickness direction is reduced, the support substrate 10 may be other than the sapphire substrate, and the piezoelectric substrate 12 may be other than the lithium tantalate substrate.

As described above, when the piezoelectric substrate 12 made of a different material from the support substrate 10 is bonded on the upper surface of the support substrate 10 at room temperature, the spurious due to the bulk wave reflected by the boundary surface occurs. The first embodiment configures the thickness T2 of the piezoelectric substrate 12 to be equal to or less than the wavelength λ of the acoustic wave excited by the comb-shaped electrode (the surface acoustic wave). This configuration reduces the spurious due to the bulk wave reflected by the boundary surface.

The thickness T2 of the piezoelectric substrate 12 is preferably less than 0.8 times greater than the wavelength λ, more preferably less than 0.5 times greater than the wavelength λ. The wavelength λ of the acoustic wave may be an average pitch of the electrode finger of the comb-shaped electrode (twice the average pitch of the electrode finger as an IDT).

The support substrate 10 may be, for example, a silicon substrate, a spinel substrate, or an alumina substrate. The piezoelectric substrate 12 may be a lithium niobate substrate, a crystal substrate, or a langasite substrate. For example, silicon has a linear thermal expansion coefficient of 3.9 ppm/° C. Thus, when the piezoelectric substrate 12 is a lithium tantalate substrate and the support substrate 10 is a sapphire substrate, the temperature characteristic of the acoustic wave device is improved.

When the support substrate 10 is a sapphire substrate and the piezoelectric substrate 12 is a lithium tantalate substrate, the total thickness T1+T2 of the support substrate 10 and the piezoelectric substrate 12 may be 150 μm or less as illustrated in FIG. 5A. Alternatively, as illustrated in FIG. 5B and FIG. 5C, T1+T2 may be configured to be 100 μm or less, or 50 μm or less.

To reduce the crack due to the temperature cycling test, T2/T1 is preferably 0.07 or less, more preferably 0.05 or less, and further preferably 0.03 or less.

The support substrate 10 may include multiple layers. That is, the support substrate 10 may include a substrate and a layer made of a different material from the substrate and formed on the substrate, and the piezoelectric substrate 12 may be bonded on the upper surface at room temperature. In this case, the piezoelectric substrate 12 is made of a different material from the substrate and the layer. Multiple layers may be formed on the substrate.

The piezoelectric substrate 12 and the support substrate 10 may be bonded together by a method using an ion implantation removing method disclosed in Japanese Patent Application Publication No. 2011-233651. That is, ion such as hydrogen is implanted into the surface of the piezoelectric substrate 12. The ion-implanted surface and the support substrate 10 are bonded together at room temperature. Then, heat treatment is conducted. This process removes the piezoelectric substrate 12 while the desired thickness of the surface is left. The above process bonds the piezoelectric substrate 12 on the support substrate 10 at room temperature.

### Second Embodiment

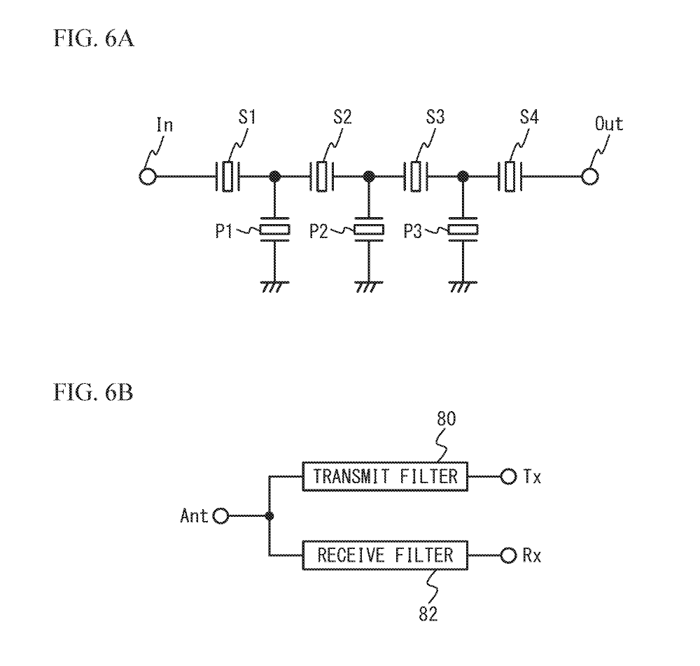

A second embodiment uses the resonator of the first embodiment for a filter or a duplexer. FIG. 6A is a circuit diagram of a ladder-type filter in accordance with a second embodiment. As illustrated in FIG. 6A, series resonators 51 through S4 are connected in series between an input terminal In and an output terminal Out. Parallel resonators P1 through P3 are connected in parallel between the input terminal In and the output terminal Out. At least one of the series resonators S1 through S4 and the parallel resonators P1 through P3 may be the resonator of the first embodiment. The number of and the connection of the series resonators and the parallel resonators are appropriately configured. A multimode filter may employ the resonator of the first embodiment.

FIG. 6B is a block diagram of a multiplexer in accordance with a variation of the second embodiment. As illustrated in FIG. 6B, a transmit filter 80 is connected between a common terminal Ant and a transmit terminal Tx. A receive filter 82 is connected between the common terminal Ant and a receive terminal Rx. The transmit filter 80 transmits signals within the transmit band to the common terminal Ant among signals input from the transmit terminal Tx, and suppresses signals in other bands. The receive filter 82 transmits signals within the receive band among signals input from the common terminal Ant, and suppresses signals in other bands. At least one of the transmit filter 80 and the receive filter 82 may be the filter of the second embodiment. A duplexer is described as the example of a multiplexer, but at least one of filters of a triplexer or a quadplexer may be the filter of the second embodiment.

### Third Embodiment

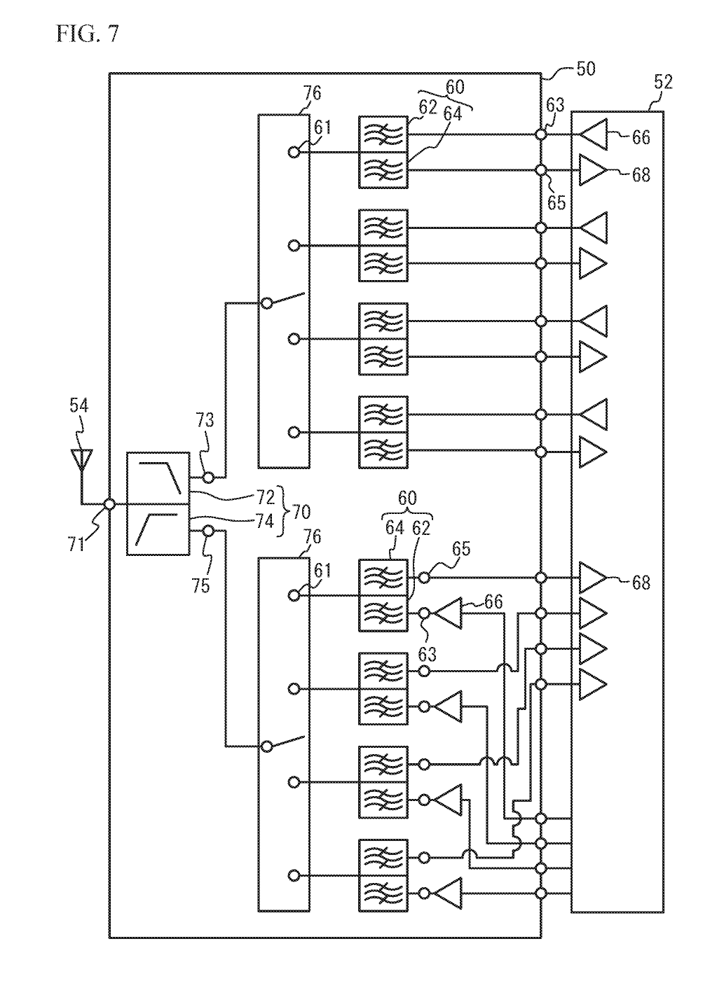

A third embodiment is an exemplary module including the ladder-type filter according to the second embodiment. FIG. 7 is a block diagram of a system including a module in accordance with a third embodiment. As illustrated in FIG. 7, the system includes a module 50, an integrated circuit 52, and an antenna 54. The module 50 includes a diplexer 70, switches 76, duplexers 60, and power amplifiers 66. The diplexer 70 includes a low-pass filter (LPF) 72 and a high-pass filter (HPF) 74. The LPF 72 is connected between terminals 71 and 73. The HPF 74 is connected between terminals 71 and 75. The terminal 71 is connected to the antenna 54. The LPF 72 allows low-frequency signals of signals transmitted from/received by the antenna 54 to pass therethrough, and suppresses high-frequency signals. The HPF 74 allows high-frequency signals of signals transmitted from/received by the antenna 54 to pass therethrough, and suppresses low-frequency signals.

The switch 76 connects the terminal 73 to one of terminals 61. The duplexer 60 includes a transmit filter 62 and a receive filter 64. The transmit filter 62 is connected between terminals 61 and 63. The receive filter 64 is connected between terminals 61 and 65. The transmit filter 62 allows signals within the transmit band to pass therethrough, and suppresses other signals. The receive filter 64 allows signals within the receive band to pass therethrough, and suppresses other signals. The power amplifier 66 amplifies and outputs a transmission signal. A low noise amplifier 68 amplifies a reception signal output to the terminal 65.

At least one of the transmit filter 62 and the receive filter 64 of the duplexer 60 may be the filter of the second embodiment. The third embodiment has described a front end module for a mobile communication terminal as an example of a module, but the module may be other kinds of modules.

Although the embodiments of the present invention have been described in detail, it is to be understood that the various change, substitutions, and alterations could be made hereto without departing from the spirit and scope of the invention.

What is claimed is:

1. An acoustic wave device comprising:
a support substrate;
a piezoelectric substrate bonded on an upper surface of the support substrate at room temperature and made of a different material from the support substrate;
a comb-shaped electrode formed on an upper surface of the piezoelectric substrate and exciting an acoustic wave; and
an amorphous layer formed between the support substrate and the piezoelectric substrate.

2. The acoustic wave device according to claim 1, wherein
the piezoelectric substrate is a lithium tantalate substrate, and
the support substrate is a sapphire substrate.

3. The acoustic wave device according to claim 2, wherein
a total thickness of the support substrate and the piezoelectric substrate is 150 μm or less.

4. The acoustic wave device according to claim 1, wherein
the amorphous layer has a thickness of 10 nm or less.

5. The acoustic wave device according to claim 4, wherein
the amorphous layer has a thickness of 1 to 8 nm.

6. The acoustic wave device according to claim 1, further comprising:
a filter including the comb-shaped electrode.

7. A module comprising:
an acoustic wave device comprising:
a support substrate;
a piezoelectric substrate bonded on an upper surface of the support substrate at room temperature and made of a different material from the support substrate;
a comb-shaped electrode formed on an upper surface of the piezoelectric substrate and exciting an acoustic wave; and
an amorphous layer formed between the support substrate and the piezoelectric substrate.
